(19) United States
(12) Patent Application Publication
(10) Pub. No.: US 2025/0323110 A1
(43) Pub. Date: Oct. 16, 2025

(54) MEMORY CELL SEALANT MATERIAL IN A THREE-DIMENSIONAL MEMORY ARRAY

(71) Applicant: Micron Technology, Inc., Boise, ID (US)

(72) Inventor: Farrell M. Good, Meridian, ID (US)

(21) Appl. No.: 18/784,815

(22) Filed: Jul. 25, 2024

Related U.S. Application Data
(60) Provisional application No. 63/632,964, filed on Apr. 11, 2024.

(51) Int. Cl. H01L 23/31; H01L 21/02; H01L 23/29; H10B 80/00

(52) U.S. Cl. CPC H01L 23/3142; H01L 21/0229; H01L 23/291; H10B 80/00

(57) ABSTRACT

Methods, systems, and devices for a memory cell sealant material in a three-dimensional memory array are described. After forming a memory cell, a sealant material may be formed. The sealant material may include some material with a relatively high dielectric constant on the memory cell. The sealant material may be located between the memory cell and a pillar and may prevent or reduce diffusion between the memory cell and the pillar while supporting the memory cell being accessed. The sealant material may be formed as one or more layers of materials and may be associated with a relatively high dielectric constant, such that the sealant material may support low temperature deposition.

### CROSS REFERENCE

The present Application for Patent claims priority to U.S. Patent Application No. 63/632,964 by Good, entitled “MEMORY CELL SEALANT MATERIAL IN A THREE-DIMENSIONAL MEMORY ARRAY,” filed Apr. 11, 2024, which is assigned to the assignee hereof, and which is expressly incorporated by reference in its entirety herein.

### TECHNICAL FIELD

The following relates to one or more systems for memory, including a memory cell sealant material in a three-dimensional memory array.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a memory array that supports a memory cell sealant material in a three-dimensional (3D) memory array in accordance with examples as disclosed herein.

FIG. 2 shows a top view of an example of a memory array that supports a memory cell sealant material in a 3D memory array in accordance with examples as disclosed herein.

FIGS. 3A and 3B show side views of an example of a memory array that supports a memory cell sealant material in a 3D memory array in accordance with examples as disclosed herein.

FIGS. 4A and 4B show respective examples of a layout and a cross-section thereof that support a memory cell sealant material in a 3D memory array in accordance with examples as disclosed herein.

FIGS. 5A and 5B show examples of a layout that supports a memory cell sealant material in a 3D memory array in accordance with examples as disclosed herein.

FIG. 6A and 6B show respective examples of cross-sections of a layout that supports a memory cell sealant material in a 3D memory array in accordance with examples as disclosed herein.

FIG. 7 shows a flowchart illustrating a method or methods that support a memory

cell sealant material in a 3D memory array in accordance with examples as disclosed herein.

### DETAILED DESCRIPTION

Some memory arrays in one or more memory systems may be three-dimensional (3D) arrays including levels of memory cells separated by layers of other materials, such as dielectric material. A memory cell may be positioned between two layers of dielectric material in a first direction (e.g., a vertical, z direction), positioned between two electrodes in a second direction (e.g., a horizontal, y direction), and positioned between a dielectric material and a pillar in a third direction (e.g., a horizontal, x direction). The pillar may initially be a hole (e.g., cavity, absence of material) that extends through the array and may be used for formation of the memory cell and other components in the array. The hole may subsequently be filled with an oxide material or some other type of material to form a structural pillar within the memory array. When memory cells are manufactured and accessed, diffusion of materials between the memory cell and other materials in contact with the memory cell, such as selenium out-diffusion and oxygen in-diffusion, may occur (e.g., due to heat associated with accessing the memory cells). For example, oxygen from the pillar may diffuse into the memory cell. The material diffusion may change material properties of the memory cell that can negatively impact performance in some cases.

After forming a memory cell, the described techniques provide for formation of a sealant material on the memory cell. The sealant material may be associated with a relatively high dielectric constant. For example, the dielectric constant of the sealant material may be greater than other dielectric constants of other materials in the pillar and the array at a threshold temperature (e.g., a deposition temperature). The sealant material may be deposited between the memory cell (e.g., a memory cell storage material) and a pillar and may prevent or reduce diffusion between the memory cell and the pillar (e.g., oxide material) while supporting the memory cell being accessed (e.g., via the electrodes). The sealant material may be formed as one or more layers of materials. In some examples, one or more of the layers of materials may include Boron, Nitrogen, or both. The relatively high dielectric constant associated with the sealant material may provide for deposition of the sealant material at a relatively low temperature, which may reduce further degradation to the memory cell and other materials.

In addition to applicability in memory systems described herein, techniques for a memory cell sealant material in a 3D memory array may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by improving reliability and protection for memory storage at a memory cell level, and may also use less power relative to other solutions, among other benefits.

Further, techniques for a memory cell sealant material in a 3D memory array may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing risk of damage and harmful diffusion to memory cells and by maintaining cell purity in endurance cycling (e.g., silanol transfer from a fill material) under cell stress. Further, the described sealant material techniques may be effective at reducing or preventing oxygen and steam from entering a memory cell. The sealant material techniques may result in improvement to mass transport, reaction space, quality, or any combination thereof related to 3D structure. This may extend the life of electronic devices and thereby reducing electronic waste, among other benefits.

Features of the disclosure are illustrated and described in the context of memory devices and arrays. Features of the disclosure are further illustrated and described in the context of memory layouts, multiple views of such memory layouts, and flowcharts.

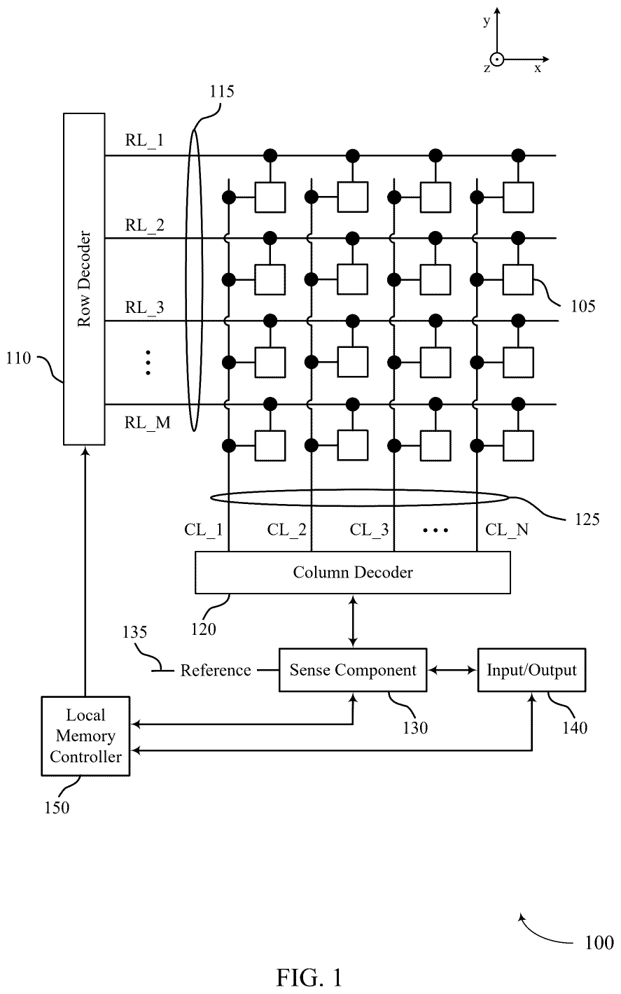

FIG. 1 shows an example of a memory device 100 that supports a memory cell sealant material in a 3D memory array in accordance with examples as disclosed herein. In some examples, the memory device 100 may be referred to as or include a memory die, a memory chip, or an electronic memory apparatus. The memory device 100 may be operable to provide locations to store information (e.g., physical memory addresses) that may be used by a system (e.g., a host device coupled with the memory device 100, for writing information, for reading information).

The memory device 100 may include one or more memory cells 105 that each may be programmable to store different logic states (e.g., a programmed one of a set of two or more possible states). For example, a memory cell 105 may be operable to store one bit of information at a time (e.g., a logic 0 or a logic 1). In some examples, a memory cell 105 (e.g., a multi-level memory cell 105) may be operable to store more than one bit of information at a time (e.g., a logic 00, logic 01, logic 10, a logic 11). In some examples, the memory cells 105 may be arranged in an array.

A memory cell 105 may store a logic state using a configurable material, which may be referred to as a memory element, a storage element, a memory storage element, a material element, a material memory element, a material portion, or a polarity-written material portion, among others. A configurable material of a memory cell 105 may refer to a chalcogenide-based storage component. For example, a chalcogenide storage element may be used in a phase change memory cell, a thresholding memory cell, or a self-selecting memory cell, among other architectures.

In some examples, the material of a memory cell 105 may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell 105 may be an example of a phase change memory cell. In such examples, the material used in the memory cell 105 may be based on an alloy (such as the alloys listed above) and may be operated so as to change to different physical state (e.g., undergo a phase change) during normal operation of the memory cell 105. For example, a phase change memory cell 105 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells 105, for self-selecting memory cells 105), some or all of the set of logic states supported by the memory cells 105 may be associated with a relatively disordered atomic configuration of a chalcogenide material (e.g., the material in an amorphous state may be operable to store different logic states). In some examples, the storage element of a memory cell 105 may be an example of a self-selecting storage element. In such examples, the material used in the memory cell 105 may be based on an alloy (e.g., such as the alloys listed above) and may be operated so as to undergo a change to a different physical state during normal operation of the memory cell 105. For example, a self-selecting or thresholding memory cell 105 may have a high threshold voltage state and a low threshold voltage state, where a corresponding “threshold voltage” may refer to a voltage at which or above which the memory cell 105 transitions from a relatively higher-resistance (e.g., non-conductive) state to a relatively lower-resistance (e.g., conductive) state, such as in response to an applied voltage. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 105, a polarity used for a write operation may influence (e.g., determine, set, program) a behavior or characteristic of the material of the memory cell 105, such as a thresholding characteristic (e.g., a threshold voltage) of the material. A difference between thresholding characteristics (e.g., resistivity characteristics, conductivity characteristics) of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

The memory device 100 may include access lines (e.g., row lines 115 each extending along an illustrative x-direction, column lines 125 each extending along an illustrative y-direction) arranged in a pattern, such as a grid-like pattern. Access lines may be formed with one or more conductive materials. In some examples, row lines 115, or some portion thereof, may be referred to as word lines. In some examples, column lines 125, or some portion thereof, may be referred to as digit lines or bit lines. References to access lines, or their analogues, are interchangeable without loss of understanding. Memory cells 105 may be positioned at intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory device 100 that includes memory cells 105 at different levels may be supported by a different configuration of access lines, decoders, and other supporting circuitry than shown.

Operations such as read operations and write operations may be performed on the memory cells 105 by activating access lines such as one or more of a row line 115 or a column line 125, among other access lines associated with alternative configurations. For example, by activating a row line 115 and a column line 125 (e.g., applying a voltage to the row line 115 or the column line 125), a memory cell 105 may be accessed in accordance with their intersection. An intersection of a row line 115 and a column line 125, among other access lines, in various two-dimensional or 3D configuration may be referred to as an address of a memory cell 105. In some examples, an access line may be a conductive line coupled with a memory cell 105 and may be used to perform access operations on the memory cell 105. In some examples, the memory device 100 may perform operations responsive to commands, which may be issued by a host device coupled with the memory device 100 or may be generated by the memory device 100 (e.g., by a local memory controller 150).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory device 100 or to a host device coupled with the memory device 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory device 100), translate the information into a signaling that can be used by the memory device 100, perform one or more operations on the memory cells 105 and communicate data from the memory device 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory device 100. In general, the amplitude, the shape, or the duration of an applied signal discussed herein may be varied and may be different for the various operations discussed in operating the memory device 100.

The local memory controller 150 may be operable to perform one or more access operations on one or more memory cells 105 of the memory device 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory device 100 that are not directly related to accessing the memory cells 105.

The memory device 100 may include a sealant material that includes some material with a relatively high dielectric constant. The sealant material may be connected to a memory cell 105. The sealant material may be located between the memory cell 105 and a pillar of the memory device 100. The pillar may include an oxide material. The sealant material may prevent or reduce diffusion between the memory cell 105 and the pillar. The memory cell 105 may be accessed via one or more electrodes. In some cases, the sealant material may be formed as one or more layers of materials. Each layer of the one or more layers may be associated with a relatively high dielectric constant. At a time of manufacture, a manufacturing system may deposit the one or more layers using relatively low temperature deposition.

The memory device 100 may include any quantity of non-transitory computer readable media that support a memory cell sealant material in a 3D memory array. For example, a local memory controller 150, a row decoder 110, a column decoder 120, a sense component 130, or an input/output component 140, or any combination thereof may include or may access one or more non-transitory computer readable media storing instructions (e.g., firmware) for performing the functions ascribed herein to the memory device 100. For example, such instructions, if executed by the memory device 100, may cause the memory device 100 to perform one or more associated functions as described herein.

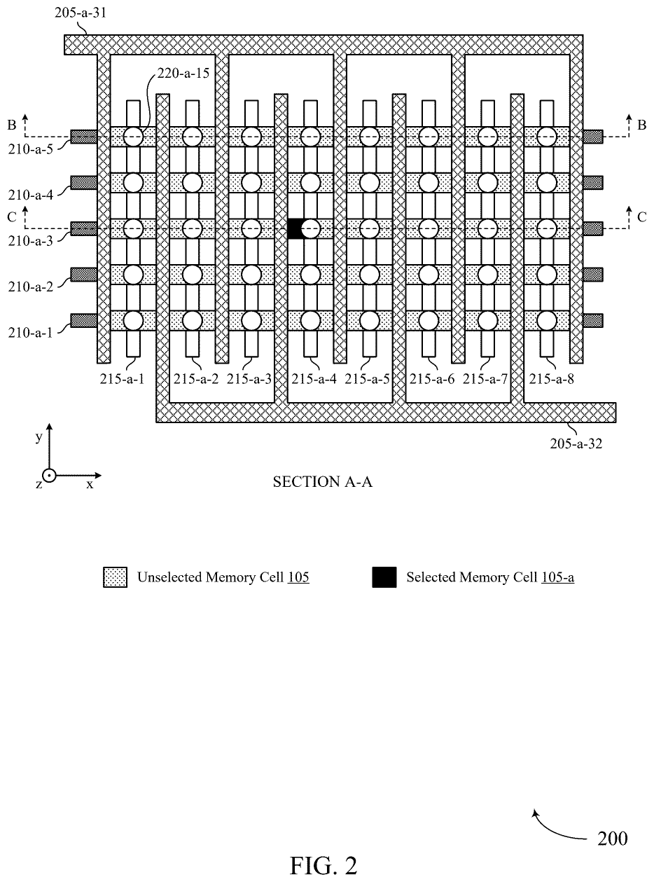

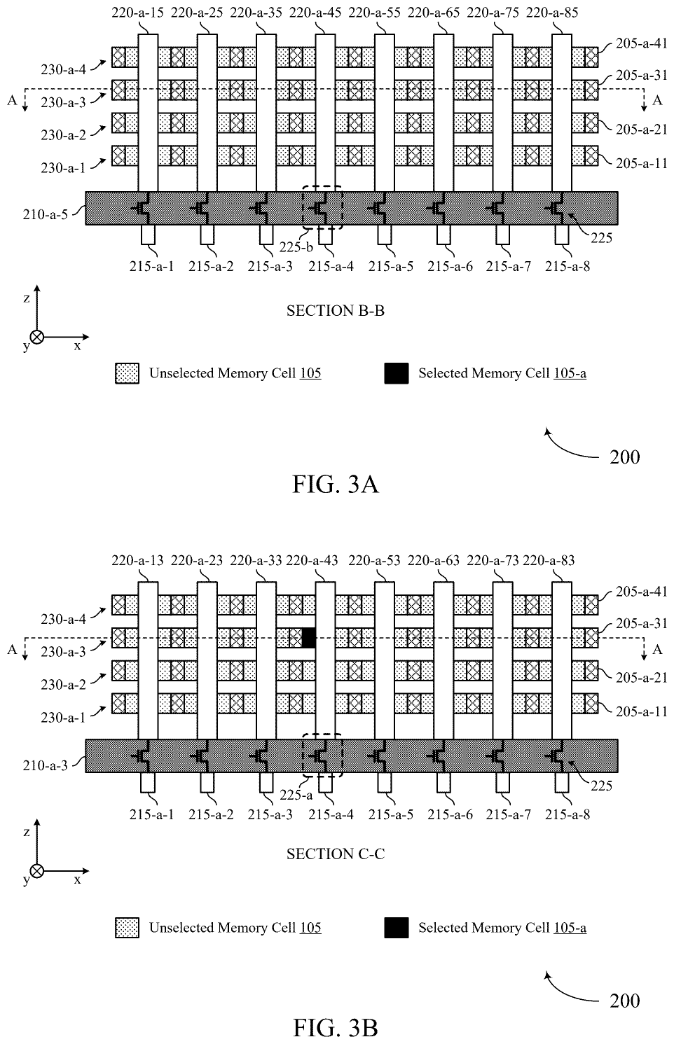

FIGS. 2, 3A, and 3B show an example of a memory array 200 that supports a memory cell sealant material in a 3D memory array in accordance with examples as disclosed herein. The memory array 200 may be included in a memory device 100, and illustrates an example of a 3D arrangement of memory cells 105 that may be accessed by various conductive structures (e.g., access lines). FIG. 2 illustrates a top section view (e.g., SECTION A-A) of the memory array 200 relative to a cut plane A-A as shown in FIGS. 3A and 3B. FIG. 3A illustrates a side section view (e.g., SECTION B-B) of the memory array 200 relative to a cut plane B-B as shown in FIG. 2. FIG. 3B illustrates a side section view (e.g., SECTION C-C) of the memory array 200 relative to a cut plane C-C as shown in FIG. 2. The section views may be examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2, 3A, and 3B. Although some elements included in FIGS. 2, 3A, and 3B are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 105 and word lines 205 may be distributed along the z-direction according to levels 230 (e.g., decks, layers, planes, tiers, as illustrated in FIGS. 3A and 3B). In some examples, the z-direction may be orthogonal to a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200, may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 105 on a first side (e.g., along the x-direction) of a given pillar 220 and an even word line (e.g., of the same level 230) may be associated with a second memory cell 105 on a second side (e.g., along the x-direction, opposite the first memory cell 105) of the given pillar 220. Thus, in some examples, memory cells 105 of a given level 230 may be addressed (e.g., selected, activated) in accordance with an even word line 205 or an odd word line 205.

Each pillar 220 may be an example of a portion of an access line (e.g., a conductive pillar portion) that is formed by one or more conductive materials (e.g., one or more metal portions, one or more metal alloy portions). As illustrated, the pillars 220 may be arranged in a two-dimensional array (e.g., in an xy-plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 105 (e.g., along the z-direction, one or more memory cells 105 for each level 230). A pillar 220 may have a cross-sectional area in an xy-plane that extends along the z-direction. Although illustrated with a circular cross-sectional area in the xy-plane, a pillar 220 may be formed with a different shape, such as having an elliptical, square, rectangular, polygonal, or other cross-sectional area in an xy-plane.

The memory cells 105 each may include a chalcogenide material. In some examples, the memory cells 105 may be examples of thresholding memory cells. Each memory cell 105 may be accessed (e.g., addressed, selected) according to an intersection between a word line 205 (e.g., a level selection, which may include an even or odd selection within a level 230) and a pillar 220. For example, as illustrated, a selected memory cell 105-a of the level 230-a-3 may be accessed according to an intersection between the pillar 220-a-43 and the word line 205-a-32.

A memory cell 105 may be accessed (e.g., written to, read from) by applying an access bias (e.g., an access voltage, V_{access}, which may be a positive voltage or a negative voltage) across the memory cell 105. In some examples, an access bias may be applied by biasing a selected word line 205 with a first voltage (e.g., V_{access}/2) and by biasing a selected pillar 220 with a second voltage (e.g., −V_{access}/2), which may have an opposite sign relative to the first voltage. Regarding the selected memory cell 105-a, a corresponding access bias (e.g., the first voltage) may be applied to the word line 205-a-32, while other unselected word lines 205 may be grounded (e.g., biased to 0V). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225 coupled between (e.g., physically, electrically) the pillar 220 and the sense line 215. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 (e.g., a channel portion of the transistors 225) may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −V_{access}/2) to the pillar 220-a-43, the sense line 215-a-4 may be biased with the access bias, and the gate line 210-a-3 may be grounded (e.g., biased to 0V) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 3A, may be biased with a voltage equal to or similar to an access bias (e.g., −V_{access}/2, or some other negative bias or bias relatively near the access bias voltage), such that transistors 225 along an unselected gate line 210 are not activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 105 may be written to by applying a write bias (e.g., where V_{access}=V_{write}, which may be a positive voltage or a negative voltage) across the memory cell 105. In some examples, a polarity of a write bias may influence (e.g., determine, set, program) a behavior or characteristic of the material of the memory cell 105, such as the threshold voltage of the material. For example, applying a write bias with a first polarity may set the material of the memory cell 105 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

In a read operation, a memory cell 105 may be read from by applying a read bias (e.g., where V_{access}=V_{read}, which may be a positive voltage or a negative voltage) across the memory cell 105. In some examples, a logic state of the memory cell 105 may be evaluated based on whether the memory cell 105 thresholds (e.g., transitions to a relatively lower-resistance or conductive state, permits current) in the presence of the applied read bias. For example, such a read bias may cause a memory cell 105 storing a first logic state (e.g., a logic 0) to threshold (e.g., permit a current flow, permit a current above a threshold current), and may not cause a memory cell 105 storing a second logic state (e.g., a logic 1) to threshold (e.g., may not permit a current flow, may permit a current below a threshold current).

In some systems, a set of memory cell chalcogenide materials may be sealed using a safe process thermally. The materials may be sealed to create a physical boundary to prevent or reduce diffusion (e.g., to keep oxygen diffusion in and SAG material diffusion out). In some systems, silicon nitride may be used for two-dimensional (2D) materials screening. One or more manufacturing systems may deposit the silicon nitride using a soft plasma-based deposition technique. In some cases, applying a low temperature silicon nitride deposition technique (e.g., with a sufficiently high quality for relatively high aspect ratio step coverage) may be undesirable (e.g., severely limiting in practice) due to a plasma requirement for the associated nitridation procedure and due to an increased damage risk to chalcogenide materials, which may be chemically and thermally sensitive. Thus, techniques which allow memory cell chalcogenide materials to be isolated (e.g., by a dielectric material) on each non-electrically active side of the memory cell are desirable. A true thermal atomic layer deposition (ALD) material seal compatible (e.g., on all sides) of a chalcogenide material may result in a desirable aspect ratio of an ALD cell deposition technique.

A manufacturing system may form the memory array 200, including one or more memory cells 105. For example, the manufacturing system may form a memory cell 105 and may form a sealant material on the memory cell 105. In some cases, the sealant material may include some material with a relatively high dielectric constant. The sealant material may be located between the memory cell 105 and a pillar including an oxide material. The scalant material may reduce diffusion between the memory cell 105 and the pillar while supporting the memory cell 105 being accessed (e.g., via a set of one or more electrodes). In some cases, the sealant material may be deposited after both the memory cell and the pier material are formed (e.g., the sealant material may be a final “edge” sealant material for the pier isolating against the pier material). The sealant material may be formed as one or more layers of materials. Further, the sealant material may be associated with a relatively high dielectric constant, such that the sealant material may support low temperature deposition.

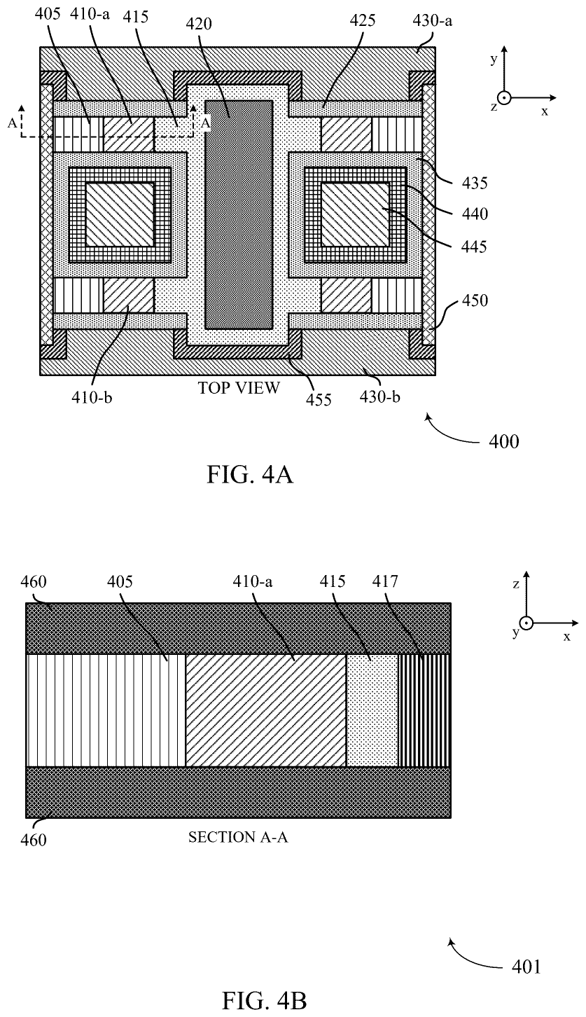

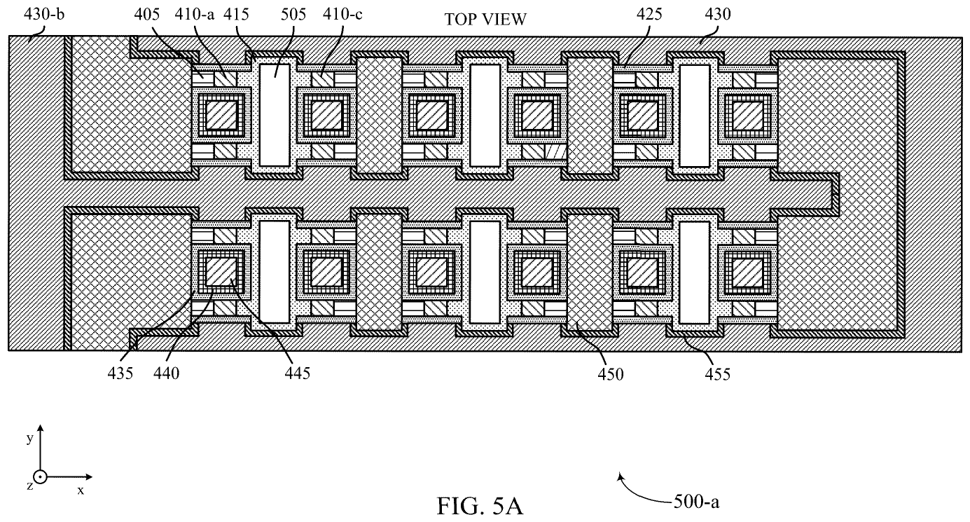

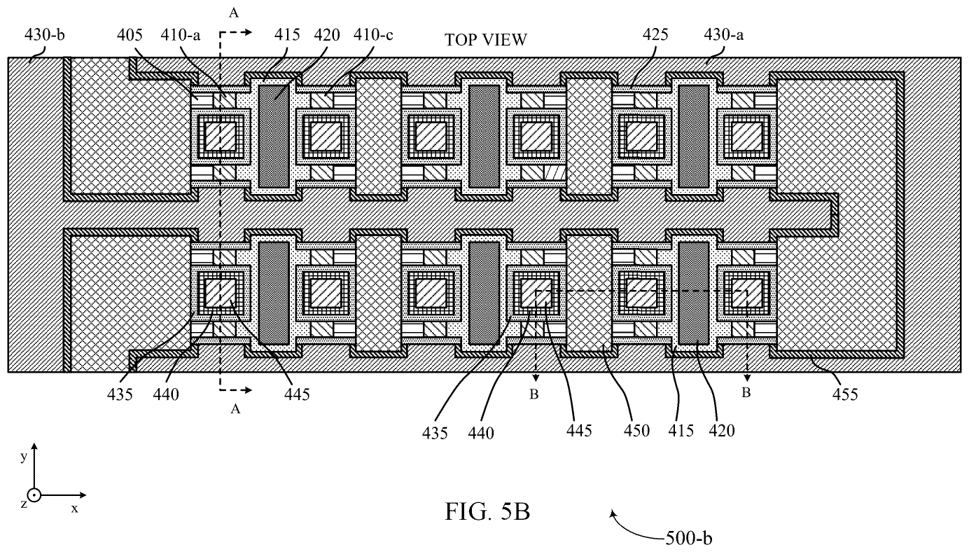

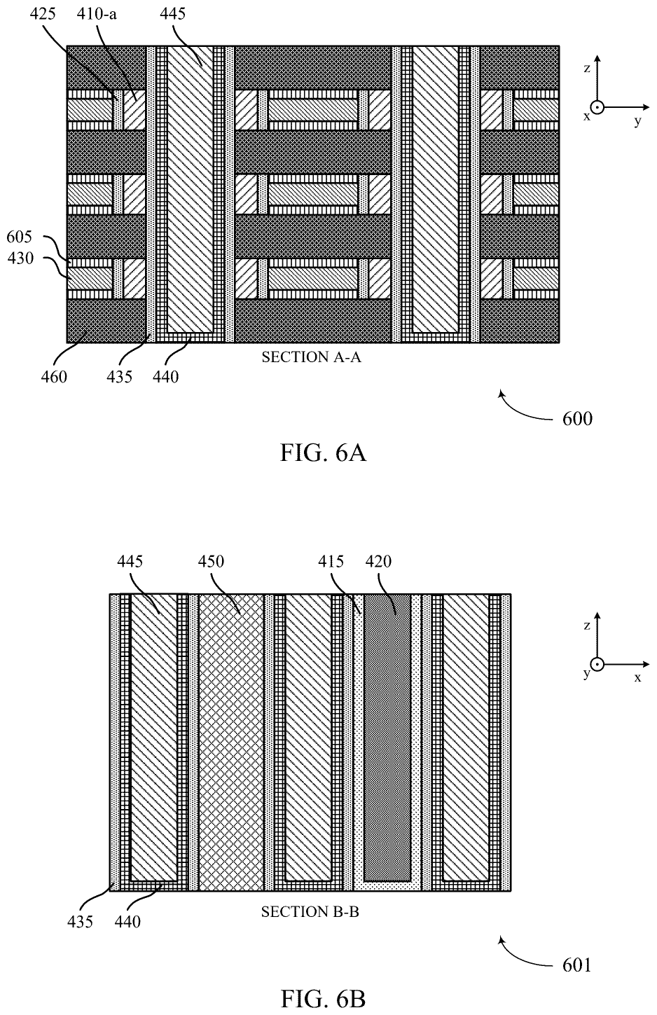

FIGS. 4 through 6 illustrate examples of memory layouts and operations that support a memory cell sealant material in a 3D memory array in accordance with examples as disclosed herein. For example, FIGS. 4A and 4B may illustrate aspects of a layout 400, which may be a portion of a memory device (e.g., a portion of a memory device 100, a portion of a memory array 200, a portion of a memory die, a portion of a layout 500). FIGS. 5A and 5B may illustrate aspects of a sequence of operations for fabricating a layout 500, which may be a portion of the memory device. Each view of the figures may be described with reference to an x-direction, a y-direction, and a z-direction, as illustrated, which may correspond to the respective directions described with reference to the memory array 200. Some of the provided figures may include section views that illustrate example cross-sections of the layout 400 and the layout 500, respectively. For example, in FIG. 4A, a view “SECTION A-A” may be associated with a cross-section 401 in an xz-plane (e.g., in accordance with a cut plane A-A) through a portion of the layout 400. FIG. 4B may illustrate the cross-section 401 in the xz-plane. In FIG. 5B, a view “SECTION A-A” may be associated with a cross-section 600 in a yz-plane (e.g., in accordance with a cut plane A-A) through a portion of the layout 500. FIG. 6A may illustrate the cross-section 600. Similarly, a view “SECTION B-B” may be associated with a cross-section 601 in an xz-plane (e.g., in accordance with a cut plane B-B) through a portion of the layout 500. FIG. 6B may illustrate the cross-section 601. Although the layouts 400 and 500 illustrate examples of certain relative dimensions and quantities of various features, aspects of the layouts 400 and 500 may be implemented with other relative dimensions or quantities of such features in accordance with examples as disclosed herein.

Operations illustrated in and described with reference to FIGS. 4 through 6 may be performed by a manufacturing system, such as a semiconductor fabrication system configured to perform additive operations such as deposition, doping, or bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 4A shows an example of a layout 400 that supports a memory cell sealant material in a 3D memory array in accordance with examples as disclosed herein. The layout 400 may be a portion of the layout 500 as described with reference to FIGS. 5A and 5B. The layout 400 may be a top-down view of a memory layout, including a set of memory cells 410 (e.g., a memory cell 410-a, a memory cell 410-b) used to store multiple logic states. In some implementations, the layout 400 may be implemented by or may include a memory device 100, a memory array 200, or both, as described with reference to FIGS. 1, 2, 3A, and 3B. In the following description of FIGS. 4A-6B, although processes, apparatuses, and operations may be discussed with reference to a single memory cell 410 (e.g., the memory cell 410-a), those processes, apparatuses, and operations may be similarly applied to other memory cells 410.

Each memory cell 410 of the set of memory cells 410 may be surrounded (e.g., in the xy-plane) by one or more components of the layout 400. For example, a first dielectric material 405 may border (or may be in contact with) each memory cell 410 on at least one side. The first dielectric material 405 may be located between each memory cell 410 and a respective pier 450 and may prevent or reduce diffusion between each memory cell 410 and the respective pier 450. The pier 450 may be a structural formation and may include one or more different types of sacrificial or structural materials.

Each memory cell 410 may be coupled with one or more electrodes. For example, a first electrode 425 may extend in a first direction (e.g., an x-direction) and may couple with a subset of memory cells 410 from one side. The first electrode 425 may couple with a word line 430-a such that the memory cell 410-a is accessible via the word line 430-a. Similarly, the memory cell 410-b may be accessible via a word line 430-b through a first electrode 425 coupled with the memory cell 410-b. A second electrode 435 may partially or fully surround a digit line 440 (e.g., in the xy-plane). The digit line 440 may further include (e.g., surround) or otherwise be in contact with a conductive material 445. The memory cell 410-a and the memory cell 410-b may be individually accessible via the digit line 440 and through the second electrode 435, which may be individually coupled with each of the memory cell 410-a and the memory cell 410-b. The digit line 440 may thus be an example of a portion of an access line (e.g., a conductive line portion) that is formed by one or more conductive materials (e.g., one or more metal portions, one or more metal alloy portions).

As described herein, the layout 400 may include a sealant material positioned between the memory cells 410 and the pillar 420. The sealant material may include at least a first sealant material 415, as illustrated in FIG. 4A. In some examples, the sealant material may additionally include a second sealant material 417, as illustrated in FIG. 4B. The sealant material may border (or may be in contact with) each memory cell 410 of the set of memory cells 410. The sealant material may also border and at least partially surround a pillar 420 (e.g., on all or most sides of the pillar in the xy-plane). The pillar 420 may include an oxide material. The sealant material may reduce or prevent diffusion between each memory cell 410 and the pillar 420. In some cases, a second dielectric material 455 may border the sealant material and each pier 450 of a set of piers 450. Thus, each pier 450 and the sealant material may be electronically isolated form the word lines 430.

FIG. 4B illustrates a cross-section 401 of the layout 400 (e.g., “Section A-A”) in the xz-plane (e.g., a “side view” of the layout 400) that supports a memory cell sealant material in a 3D memory array in accordance with examples as disclosed herein. The cross-section 401 includes the first dielectric material 405 adjacent to (or in contact with) the memory cell 410-a. In some cases, the sealant material may include a first sealant material 415 that is in contact with the memory cell 410-a. Additionally, or alternatively, the sealant material may include a second sealant material 417. In some cases, although not pictured in FIG. 4B, the second sealant material 417 may be in contact with the memory cell 410-a and positioned between the first sealant material 415 and the memory cell 410-a. In some examples, a third dielectric material 460 may extend in the first direction (e.g., x-direction) and be in contact with the first dielectric material, the memory cell 410-a, the first sealant material, the second sealant material, or any combination thereof. The second dielectric material 455 and the third dielectric material 460 may be a same dielectric material or a different dielectric material. In some examples, the memory array may be formed as a stack of alternating material layers, including dielectric material layers, and the dielectric material 460 may represent two of the dielectric material layers.

FIG. 5A shows an example of a layout 500-a after a first set of one or more manufacturing operations that supports a memory cell sealant material in a 3D memory array in accordance with examples as disclosed herein. The layout 500-a may include one or more components illustrated in the layout 400. For example, the layout 500-a may include a first dielectric material 405, a set of memory cells 410, a sealant material (e.g., a first sealant material 415, a second sealant material 417), a set of first electrodes 425, a set of word lines 430, a set of second electrodes 435, a set of digit lines 440 (each including a conductive material 445), a set of piers 450 (e.g., structural piers), a second dielectric material 455, or any combination thereof. In some examples, the layout 500-a may represent a “zoomed-out” version of the layout 400. For example, the layout 500-a may include the layout 400 as well as one or more additional regions or portions of the memory array.

The layout 500-a may be an example of a top-down view of a of a stack of materials after the first set of one or more manufacturing operations. The first set of one or more manufacturing operations may include forming the stack of materials over a substrate. The stack of materials may include layers of a first material (e.g., a sacrificial material) and layers of a dielectric material.

The first set of one or more manufacturing operations may include removing a portion of the first material and a portion of the dielectric material to form a hole 505 (e.g., a cavity, recess, or other absence of material) that extends through the stack of materials (e.g., the portions of the first material and the dielectric material may be exhumed to form the hole 505). A portion of at least one layer of the first material may be removed, and a cavity may be formed between a first layer of the dielectric material and a second layer of the dielectric material. The cavity may be positioned between the first electrode 425 and the second electrode 435 in the layer. A similar cavity may be formed in each layer of the stack of materials, in some examples. For example, the first material may be exhumed or etched within each layer of the stack (e.g., in the z-direction) and removed via the holes 505, such that multiple cavities may remain in the layers and in contact with the holes 505. A memory cell storage material may be deposited into the holes 505, which may fill the cavities. The memory cell storage material may be selectively deposited into the cavities or may be deposited and subsequently etched such that the storage material fills a portion of the cavities, as illustrated by the cross-sectional view of the memory cells 410 in FIG. 6A. Thus, a memory cell 410 may be formed in a first portion of the cavity and in contact with the first electrode 425 and the second electrode 435. In some examples, the electrodes 425 and 435 may be formed prior to the memory cells 410 by deposition of a conductive material via the hole 505, or some other method.

In some cases, the first set of one or more manufacturing operations may include depositing a set of materials to form a subset of components prior to forming the memory cell 410 and prior to depositing the sealant material. For example, the subset of components may include a first electrode 425, a second electrode 435, a first dielectric material 405 (e.g., materials that surround the memory cell 410). One or more conductive materials (e.g., titanium nitride (TiN), tantalum nitride (TaN), or similar conductive materials) may be deposited to form the first electrode 425, the second electrode 435, or both. In some examples, one or more dielectric materials (e.g., silicon nitride) may be deposited to form the first dielectric material 405 (e.g., to isolate the memory cell 410 from a pier 450). In some cases, one or more dielectric materials (e.g., silicon dioxide (SiO2) or silicate) may be deposited to form the third dielectric material 460, as described and illustrated with reference to FIGS. 4B and 6A.

The first set of one or more manufacturing operations may further include forming one or more digit lines 440 that extend through the stack of materials. As illustrated, the digit lines 440 may be distributed across the xy-plane, having a first quantity of digit lines 440 along a first direction (e.g., six digit lines along the x-direction), and having a second quantity of digit lines 440 along a second direction (e.g., two digit lines along the y-direction). Although the illustrative example of the layout 500-a illustrates a two-dimensional arrangement of six digit lines 440 along the x-direction and two digit lines 440 along the y-direction, a layout 500-a in accordance with examples as disclosed herein may include any quantity of digit lines 440 along the x-direction and any quantity of digit lines 440 along the y-direction. Further, as illustrated, each digit line 440 may extend vertically along the z-direction through the stack of materials to a substrate of the memory device and may be coupled with a respective set of memory cells 410 (e.g., along the z-direction, one or more memory cells 410 for each level or layer). That is, the cross-sectional area in an xy-plane of each digit line 440 illustrated in FIG. 5A may extend along the z-direction. Although illustrated with a square cross-sectional area in the xy-plane, a digit line 440 may be formed with a different shape, such as having an elliptical, circular, rectangular, polygonal, or other cross-sectional area in an xy-plane. The respective arrangements illustrated in FIGS. 5A and 5B corresponding to holes 505 (or pillars 420), piers 450, memory cells 410, and other components may be interpreted similarly.

The first set of one or more manufacturing operations may further include depositing the first sealant material 415 (and/or the second sealant material 417) in a second portion of the cavities using an ALD procedure (e.g., plasma enhanced ALD (PEALD)). That is the sealant material may be an example of an ALD seal material. The sealant material 415 may be deposited after the other elements illustrated in FIG. 5A are formed. That is, the deposition of the sealant material 415 may be the final step in the first set of one or more manufacturing operations, in some examples. The first sealant material 415 may have a first dielectric constant. The second sealant material 417 may have a second dielectric constant. At a threshold temperature (e.g., a deposition temperature), the first dielectric constant (and/or the second dielectric constant) may be greater than one or more other dielectric constants of one or more other materials in the layout 500-a (e.g., all other dielectric constants of the one or more other materials). For example, the first sealant material 415 may include hafnium oxide (HfOx), hafnium silicate (HfSiOx), zirconium oxide (ZrOx), zirconium silicate (ZrSiOx), another material with a relatively high dielectric constant, or any combination thereof. The first sealant material 415 may be deposited in an ALD mode below a glass transition temperature and with an oxygen reaction (e.g., a relatively low-energy oxygen reaction to prevent damage to materials such as a chalcogenide material of the memory cell 410).

The second sealant material 417 may be deposited as a second layer film of Boron (B) or Boron Nitride (BN). In some cases, the second sealant material 417 may include other materials such as a silicon-boron oxide material (SixByOz), a silicon-boron nitride material (BSiN), an aluminum nitride material (AlN), an aluminum-boron nitride material (AlBN), a hafnium nitride nitride material (HfN), a TaN material, or any combination thereof (e.g., materials that support thermal and diffusion barrier properties of the memory cell 410). The second sealant material 417 may protect against oxygen diffusion, damage, or both, from a post-gap-fill process that isolates (e.g., closes off) a cell deposition access point in the pier 450. Thus, the sealant material may be a final “edge” seal for the pier 450, isolating against the pier 450 (e.g., a silicon oxide refill material).

After depositing the sealant material (e.g., including the first sealant material 415, the second sealant material 417, or both), a manufacturing system may perform operations involving oxygen-containing dielectrics (e.g., oxygen-containing operations or processes), as described in further detail elsewhere herein, including with reference to FIG. 5B.

FIG. 5B shows an example of a layout 500-a after a second set of one or more manufacturing operations that supports a memory cell sealant material in a 3D memory array in accordance with examples as disclosed herein. The second set of one or more manufacturing operation may include depositing an oxide material in the hole 505 to form the pillar 420. The memory cell 410 may be isolated from the oxide material based on the first sealant material 415, the second sealant material 417, or both. Further, the first dielectric constant of the first sealant material 415, the second dielectric constant of the second sealant material 417, or both may be greater than one or more other materials in the pillar 420. Thus, the sealant material (e.g., the first sealant material 415 and/or the second sealant material 417) may prevent or reduce diffusion between the memory cell 410 and the pillar 420.

During the second set of one or more manufacturing operations, the sealant material(s) may prevent or reduce oxygen diffusion. Thus, the sealant material may be compatible (e.g., chemically and thermally) with the memory cell 410. Further, the sealant material may provide a sufficient seal or barrier against elements or materials that increase diffusion risk. The sealant material may isolate the memory cell 410 against oxygen that is present during a gap fill (e.g., a final gap fill) or during post-processing (e.g., diffusion occurring after the gap fill).

FIG. 6A shows an example of a cross-section 600 of the layout 500 (e.g., “Section A-A” of the layout 500-b) in the yz-plane (e.g., a “side view” of the layout 500) that supports a memory cell sealant material in a 3D memory array in accordance with examples as disclosed herein. For example, the cross-section 600 may illustrate a different perspective of one or more components of the layout 500-b.

The cross-section 600 may illustrate a set of memory cells 410, a set of first electrodes 425, a set of word lines 430, a set of second electrodes 435, a set of digit lines 440 (including a conductive material 445), a third dielectric material 460 (as described with reference to FIG. 4B), or any combination thereof. The set of second electrodes may be positioned on either side of the digit line 440 in the cross-section 600, but it is noted that the second electrode may at least partially surround the digit line (e.g., forming a cylindrical shell, or other 3D shell, around the digit line), in some examples. Further, the cross-section 600 may include a fourth dielectric material 605. The fourth dielectric material 605 may isolate each word line 430 of the set of word lines 430 from the third dielectric material 460. In some cases, the fourth dielectric material 605 may be a same dielectric material as the second dielectric material 455, the third dielectric material 460, or both.

FIG. 6B shows an example of a cross-section 601 of the layout 500 (e.g., “Section B-B” of the layout 500-b) in the xz-plane (e.g., a “side view” of the layout 500) that supports a memory cell sealant material in a 3D memory array in accordance with examples as disclosed herein. For example, the cross-section 600 may illustrate a different perspective of one or more components of the layout 500-b.

The cross-section 600 may illustrate a sealant material (e.g., a first sealant material 415 and/or a second sealant material 417 as described with reference to FIGS. 4A-5B), a pillar 420, one or more electrodes 435, a set of digit lines 440 (including a conductive material 445, a pier 450, or any combination thereof). After the first set of one or more manufacturing operations described with reference to FIG. 5A, the cross-section 600 may include a hole 505. The second set of one or more manufacturing operations described with reference to FIG. 5B may include depositing oxygen in the hole 505 to form the pillar 420. The electrode 435 may be positioned on either side of the digit line 440 in the cross-section 600 and the cross-section 601 because the second electrode 435 may at least partially surround the digit line 440. Similarly, the sealant material 415 may isolate the pillar 420 from the electrode 435 and the set of memory cells 410 as described with reference to FIG. 4A.

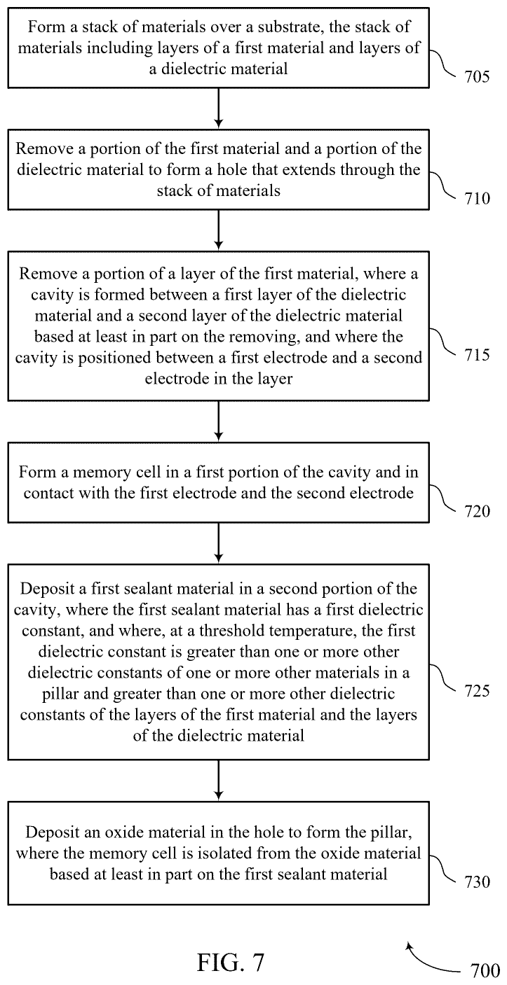

FIG. 7 shows a flowchart illustrating a method 700 that supports a memory cell sealant material in a 3D memory array in accordance with examples as disclosed herein. The operations of method 700 may be implemented by a manufacturing system or its components as described herein. For example, the operations of method 700 may be performed by a manufacturing system as described with reference to FIGS. 1 through 6. In some examples, a manufacturing system may execute a set of instructions to control the functional elements of the device to perform the described functions. Additionally, or alternatively, the manufacturing system may perform aspects of the described functions using special-purpose hardware.

At 705, the method may include forming a stack of materials over a substrate, the stack of materials including layers of a first material and layers of a dielectric material.

At 710, the method may include removing a portion of the first material and a portion of the dielectric material to form a hole that extends through the stack of materials.

At 715, the method may include removing a portion of a layer of the first material, where a cavity is formed between a first layer of the dielectric material and a second layer of the dielectric material based at least in part on the removing, and where the cavity is positioned between a first electrode and a second electrode in the layer.

At 720, the method may include forming a memory cell in a first portion of the cavity and in contact with the first electrode and the second electrode.

At 725, the method may include depositing a first sealant material in a second portion of the cavity, where the first sealant material has a first dielectric constant, and where, at a threshold temperature, the first dielectric constant is greater than one or more other dielectric constants of one or more other materials in a pillar and greater than one or more other dielectric constants of the layers of the first material and the layers of the dielectric material.

At 730, the method may include depositing an oxide material in the hole to form the pillar, where the memory cell is isolated from the oxide material based at least in part on the first sealant material.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a stack of materials over a substrate, the stack of materials including layers of a first material and layers of a dielectric material; removing a portion of the first material and a portion of the dielectric material to form a hole that extends through the stack of materials; removing a portion of a layer of the first material, where a cavity is formed between a first layer of the dielectric material and a second layer of the dielectric material based at least in part on the removing, and where the cavity is positioned between a first electrode and a second electrode in the layer; forming a memory cell in a first portion of the cavity and in contact with the first electrode and the second electrode; depositing a first sealant material in a second portion of the cavity, where the first sealant material has a first dielectric constant, and where, at a threshold temperature, the first dielectric constant is greater than one or more other dielectric constants of one or more other materials in a pillar and greater than one or more other dielectric constants of the layers of the first material and the layers of the dielectric material; and depositing an oxide material in the hole to form the pillar, where the memory cell is isolated from the oxide material based at least in part on the first sealant material.

Aspect 2: The method, apparatus, or non-transitory computer-readable medium of aspect 1, where depositing the first sealant material includes operations, features, circuitry, logic, means, or instructions, or any combination thereof for depositing the first sealant material in the second portion of the cavity and the hole, where the first sealant material forms a liner that extends along sidewalls of the hole and sidewalls of one or more cavities formed within the layers of the first material in the stack of materials.

Aspect 3: The method, apparatus, or non-transitory computer-readable medium of aspect 2, where a thickness of the liner along the sidewalls of the hole and the sidewalls of the one or more cavities is greater than a threshold thickness.

Aspect 4: The method, apparatus, or non-transitory computer-readable medium of any of aspects 1 through 3, further including operations, features, circuitry, logic, means, or instructions, or any combination thereof for depositing, after depositing the first sealant material in the second portion of the cavity and before depositing the oxide material in the hole, a second sealant material in a third portion of the cavity and in the hole, where the second sealant material includes Boron, Nitrogen, or both, and where the memory cell is further isolated from the oxide material based at least in part on the second sealant material.

Aspect 5: The method, apparatus, or non-transitory computer-readable medium of aspect 4, where depositing the second sealant material includes operations, features, circuitry, logic, means, or instructions, or any combination thereof for growing a Boron material on a surface of the first sealant material and nitriding the Boron material on the surface of the first sealant material based at least in part on an ammonia exposure, a plasma exposure, or both.

Aspect 6: The method, apparatus, or non-transitory computer-readable medium of any of aspects 1 through 5, further including operations, features, circuitry, logic, means, or instructions, or any combination thereof for exposing the first sealant material to a Boron material, where the first sealant material includes a first layer and a second layer, and where the second layer is doped with the Boron material based at least in part on exposing the first sealant material to the Boron material.

Aspect 7: The method, apparatus, or non-transitory computer-readable medium of any of aspects 1 through 6, where depositing the first sealant material includes operations, features, circuitry, logic, means, or instructions, or any combination thereof for performing, after forming the memory cell, an atomic layer deposition to deposit the first sealant material at a temperature that is less than or equal to the threshold temperature.

Aspect 8: The method, apparatus, or non-transitory computer-readable medium of any of aspects 1 through 7, where depositing the oxide material includes operations, features, circuitry, logic, means, or instructions, or any combination thereof for performing, after depositing the first sealant material, an atomic layer deposition to deposit the oxide material at a temperature that is less than or equal to the threshold temperature.

Aspect 9: The method, apparatus, or non-transitory computer-readable medium of any of aspects 1 through 8, where the first sealant material includes hafnium oxide, hafnium silicate, zirconium oxide, zirconium silicate, hafnium aluminum oxide, zirconium aluminum oxide, zirconium silicate nitride, or any combination thereof.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: An apparatus, including: a plurality of levels of a memory array arranged over a substrate and each separated from each other by at least one respective layer of a plurality of layers of a dielectric material, where, at each level of the plurality of levels, one or more memory cells of the memory array are coupled with a respective word line that extends in a first direction; a pillar that extends through the plurality of levels of the memory array in a second direction that is different from the first direction; and a sealant material that is located between each memory cell of the one or more memory cells and the pillar, where the sealant material has a first dielectric constant, and where, at a threshold temperature, the first dielectric constant is greater than one or more other dielectric constants of one or more other materials in the pillar and one or more other materials in the plurality of levels of the memory array.

Aspect 11: The apparatus of aspect 10, further including: a second sealant material that extends along the pillar, where the second sealant material is located between the sealant material and the pillar, and where the second sealant material includes Boron, Nitrogen, or both.

Aspect 12: The apparatus of any of aspects 10 through 11, further including: a digit line that extends through the plurality of levels of the memory array in the second direction, where, at each level of the plurality of levels, an electrode material at least partially surrounds the digit line.

Aspect 13: The apparatus of aspect 12, where at each level of the plurality of levels, a subset of the one or more memory cells is coupled with the digit line via the electrode material.

Aspect 14: The apparatus of any of aspects 12 through 13, where at each level of the plurality of levels, the sealant material is located between the electrode material and the pillar.

Aspect 15: The apparatus of any of aspects 10 through 14, where the sealant material at least partially surrounds the pillar and extends in the second direction, and a thickness of the sealant material along the pillar and the one or more memory cells is greater than a threshold thickness.

Aspect 16: The apparatus of any of aspects 10 through 15, where the sealant material at least partially surrounds the pillar and extends in the second direction, and at each level of the plurality of levels of the memory array, the sealant material extends in the first direction between each respective memory cell and the pillar within a portion of each respective level that is located between two layers of dielectric material of the plurality of layers of dielectric material of the apparatus.

Aspect 17: The apparatus of any of aspects 10 through 16, where the sealant material includes hafnium oxide, hafnium silicate, zirconium oxide, zirconium silicate, hafnium aluminum oxide, zirconium aluminum oxide, zirconium silicate nitride, or any combination thereof.

Aspect 18: The apparatus of any of aspects 10 through 17, where the pillar includes an oxide material.

An apparatus is described. The following provides an overview of aspects of the apparatus as described herein:

Aspect 19: An apparatus, including: a plurality of word line combs stacked in a second direction over a substrate, each word line comb of the plurality of word line combs including one or more word line fingers that extend in a first direction; a plurality of levels of a memory array arranged over the substrate and separated from each other in the second direction by a respective layer of a plurality of layers of a dielectric material, where, at each level of the plurality of levels, one or more memory cells of the memory array are coupled with a respective word line finger; a digit line that extends in the second direction through the plurality of levels of the memory array and the plurality of layers of the dielectric material, where, at each level of the plurality of levels, the one or more memory cells are coupled with the digit line via a respective electrode material; a pillar that extends in the second direction through the plurality of levels of the memory array and the plurality of layers of the dielectric material, where, at each level of the plurality of levels, the respective electrode material is located between the pillar and the digit line; and a sealant material that at least partially surrounds the pillar and extends in the second direction through the plurality of levels of the memory array and the plurality of layers of the dielectric material, where the sealant material is associated with a dielectric constant that is greater than other dielectric constants of other materials in the pillar and other materials in the plurality of levels of the memory array at a threshold temperature.

Aspect 20: The apparatus of aspect 19, further including: a second sealant material located between the sealant material and the pillar, where the second sealant material includes Boron, Nitrogen, or both.

Aspect 21: The apparatus of any of aspects 19 through 20, where at each level of the plurality of levels, the sealant material is located between the respective electrode material and the pillar.

Aspect 22: The apparatus of any of aspects 19 through 21, where a thickness of the sealant material along the pillar and the one or more memory cells is greater than a threshold thickness.

Aspect 23: The apparatus of any of aspects 19 through 22, where the sealant material includes hafnium oxide, hafnium silicate, zirconium oxide, zirconium silicate, hafnium aluminum oxide, zirconium aluminum oxide, zirconium silicate nitride, or any combination thereof.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a 3D structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a plurality of levels of a memory array arranged over a substrate and each separated from each other by at least one respective layer of a plurality of layers of a dielectric material, wherein, at each level of the plurality of levels, one or more memory cells of the memory array are coupled with a respective word line that extends in a first direction;
a pillar that extends through the plurality of levels of the memory array in a second direction that is different from the first direction; and
a sealant material that is located between each memory cell of the one or more memory cells and the pillar, wherein the sealant material has a first dielectric constant, and wherein, at a threshold temperature, the first dielectric constant is greater than one or more other dielectric constants of one or more other materials in the pillar and one or more other materials in the plurality of levels of the memory array.

2. The apparatus of claim 1, further comprising:
a second sealant material that extends along the pillar, wherein the second sealant material is located between the sealant material and the pillar, and wherein the second sealant material comprises Boron, Nitrogen, or both.

3. The apparatus of claim 1, further comprising:
a digit line that extends through the plurality of levels of the memory array in the second direction, wherein, at each level of the plurality of levels, an electrode material at least partially surrounds the digit line.

4. The apparatus of claim 3, wherein at each level of the plurality of levels, a subset of the one or more memory cells is coupled with the digit line via the electrode material.

5. The apparatus of claim 3, wherein at each level of the plurality of levels, the sealant material is located between the electrode material and the pillar.

6. The apparatus of claim 1, wherein:
the sealant material at least partially surrounds the pillar and extends in the second direction, and
a thickness of the sealant material along the pillar and the one or more memory cells is greater than a threshold thickness.

7. The apparatus of claim 1, wherein:
the sealant material at least partially surrounds the pillar and extends in the second direction, and
at each level of the plurality of levels of the memory array, the sealant material extends in the first direction between each respective memory cell and the pillar within a portion of each respective level that is located between two layers of dielectric material of the plurality of layers of dielectric material of the apparatus.

8. The apparatus of claim 1, wherein the sealant material comprises hafnium oxide, hafnium silicate, zirconium oxide, zirconium silicate, hafnium aluminum oxide, zirconium aluminum oxide, zirconium silicate nitride, or any combination thereof.

9. The apparatus of claim 1, wherein the pillar comprises an oxide material.

10. A method, comprising:
forming a stack of materials over a substrate, the stack of materials comprising layers of a first material and layers of a dielectric material;
removing a portion of the first material and a portion of the dielectric material to form a hole that extends through the stack of materials;
removing a portion of a layer of the first material, wherein a cavity is formed between a first layer of the dielectric material and a second layer of the dielectric material based at least in part on the removing, and wherein the cavity is positioned between a first electrode and a second electrode in the layer;
forming a memory cell in a first portion of the cavity and in contact with the first electrode and the second electrode;
depositing a first sealant material in a second portion of the cavity, wherein the first sealant material has a first dielectric constant, and wherein, at a threshold temperature, the first dielectric constant is greater than one or more other dielectric constants of one or more other materials in a pillar and greater than one or more other dielectric constants of the layers of the first material and the layers of the dielectric material; and
depositing an oxide material in the hole to form the pillar, wherein the memory cell is isolated from the oxide material based at least in part on the first sealant material.

11. The method of claim 10, wherein depositing the first sealant material comprises:
depositing the first sealant material in the second portion of the cavity and the hole, wherein the first sealant material forms a liner that extends along sidewalls of the hole and sidewalls of one or more cavities formed within the layers of the first material in the stack of materials.

12. The method of claim 11, wherein a thickness of the liner along the sidewalls of the hole and the sidewalls of the one or more cavities is greater than a threshold thickness.

13. The method of claim 10, further comprising:
depositing, after depositing the first sealant material in the second portion of the cavity and before depositing the oxide material in the hole, a second sealant material in a third portion of the cavity and in the hole, wherein the second sealant material comprises Boron, Nitrogen, or both, and wherein the memory cell is further isolated from the oxide material based at least in part on the second sealant material.

14. The method of claim 13, wherein depositing the second sealant material comprises:
growing a Boron material on a surface of the first sealant material; and
nitriding the Boron material on the surface of the first sealant material based at least in part on an ammonia exposure, a plasma exposure, or both.

15. The method of claim 10, further comprising:
exposing the first sealant material to a Boron material, wherein the first sealant material comprises a first layer and a second layer, and wherein the second layer is doped with the Boron material based at least in part on exposing the first sealant material to the Boron material.

16. The method of claim 10, wherein depositing the first sealant material comprises:
performing, after forming the memory cell, an atomic layer deposition to deposit the first sealant material at a temperature that is less than or equal to the threshold temperature.

17. The method of claim 10, wherein depositing the oxide material comprises:
performing, after depositing the first sealant material, an atomic layer deposition to deposit the oxide material at a temperature that is less than or equal to the threshold temperature.

18. The method of claim 10, wherein the first sealant material comprises hafnium oxide, hafnium silicate, zirconium oxide, zirconium silicate, hafnium aluminum oxide, zirconium aluminum oxide, zirconium silicate nitride, or any combination thereof.

19. An apparatus, comprising:
a plurality of word line combs stacked in a second direction over a substrate, each word line comb of the plurality of word line combs comprising one or more word line fingers that extend in a first direction;
a plurality of levels of a memory array arranged over the substrate and separated from each other in the second direction by a respective layer of a plurality of layers of a dielectric material, wherein, at each level of the plurality of levels, one or more memory cells of the memory array are coupled with a respective word line finger;
a digit line that extends in the second direction through the plurality of levels of the memory array and the plurality of layers of the dielectric material, wherein, at each level of the plurality of levels, the one or more memory cells are coupled with the digit line via a respective electrode material;
a pillar that extends in the second direction through the plurality of levels of the memory array and the plurality of layers of the dielectric material, wherein, at each level of the plurality of levels, the respective electrode material is located between the pillar and the digit line; and
a sealant material that at least partially surrounds the pillar and extends in the second direction through the plurality of levels of the memory array and the plurality of layers of the dielectric material, wherein the sealant material is associated with a dielectric constant that is greater than other dielectric constants of other materials in the pillar and other materials in the plurality of levels of the memory array at a threshold temperature.

20. The apparatus of claim 19, further comprising:
a second sealant material located between the sealant material and the pillar, wherein the second sealant material comprises Boron, Nitrogen, or both.

21. The apparatus of claim 19, wherein at each level of the plurality of levels, the sealant material is located between the respective electrode material and the pillar.

22. The apparatus of claim 19, wherein a thickness of the sealant material along the pillar and the one or more memory cells is greater than a threshold thickness.

23. The apparatus of claim 19, wherein the sealant material comprises hafnium oxide, hafnium silicate, zirconium oxide, zirconium silicate, hafnium aluminum oxide, zirconium aluminum oxide, zirconium silicate nitride, or any combination thereof.
